(19) United States
(12) Patent Application Publication
(10) Pub. No.: US 2015/0270467 A1
(43) Pub. Date: Sep. 24, 2015

(54) Thermoelectric Element

(71) Applicant: Green Rich Technology Co., Ltd., Miaoli County (TW)

(72) Inventors: Shih-Jue Lin, Miaoli County (TW); Yao-Shing Chen, Miaoli County (TW)

(21) Appl. No.: 14/656,906

(22) Filed: Mar. 13, 2015

(30) Foreign Application Priority Data
Mar. 20, 2014 (TW) 103110525

(51) Int. Cl. H01L 35/32

(52) U.S. Cl. CPC H01L 35/32

(57) ABSTRACT

A thermoelectric element includes a first subelement and a second subelement. The first subelement includes three main ingredients: a charge generation material made of organic or organic metal pigment or dye, an organic hole transport material, and a binder. A second subelement is superimposed on the first subelement and includes three main ingredients: a charge generation material made of organic or organic metal pigment or dye, an organic electron transport material, and a binder.

### BACKGROUND OF THE INVENTION

The present invention relates to a thermoelectric element and, more particularly, to an element using a material capable of carrying out photovoltaics and cooperating with transport doping for selective conduction of positive/negative charge carrier, both of which, when mixed in any non-conductive or conductive polymer, can form a semiconductor material with the properties of semiconductor materials of P-type, N-type or both; namely, an element that can generate a potential difference when subject to light or a temperature difference or generate light or a temperature difference when an applied potential difference is applied.

In the past few decades, polymers or organic materials have been used to produce electronic elements or thermoelectric elements. Electronic elements were produced in 1977 by using materials like conjugated polymers. Namely, Heeger, MacDiarmi, and Hideki Shirakawa doped polyacetylene (PA) by electrochemical and chemical methods to obtain conductive polymers in 1977.

Polyacetylene is formed by long-chain carbon molecules by sp² bonds. A sp² bond includes a σ-σ bond (a single bond) and a double bond formed by π bonds of overlapped p orbitals. During the alternate binding of the single bond and the double bond, the electrons on the p orbitals are nonlocalized along the molecular main chain to form conjugated binding of the mixed molecular orbitals. With the increase in the polymerization degree, an energy band is formed by gradual overlapping, and the Eg value of the energy bandgap gradually decreases as the degree of conjugation increases. The final Eg value is about 1.4 eV, while the Eg values of the other conjugated polymers are in a range of 1.0-3.5 eV, which is the main features of semiconductor materials. The Eg value of metal is 0 eV, and the Eg values of insulating materials are far greater than 3.5 eV. Since σ electrons cannot move along the main chain while π electrons move much easier and are pretty localized, it is necessary to conduct doping (i.e., removing a portion of electrons from the main chain (oxidation) or injecting a number of electrons (reduction), wherein these holes or additional electrons can move along the molecular chain (the energy level is in the energy bandgap) to turn the polymer into a conductor). In 1990, J. H. Burroughes et al. at Cambridge University in the United Kingdom found poly(para phenylene vinylene (PPV) could also be produced into a single layer of organic light-emitting diode. The above conjugated polymer materials include trans-polyacetylene (t-PA), poly para-phenylene (PPP), and poly para-phenylenevinylene (PPV).

In view of the foregoing, in order to make a conjugated polymer conductive, it is necessary to conduct doping; namely, a simple material is doped with a small amount of impurities to change the carrier mobility and the conductivity (which is similar to a doped semiconductor whose conductivity can be increased by charge carriers) to thereby improve application of this material in electronic elements.

In application of a thermoelectric element generating electricity by a temperature difference or providing thermoelectric cooling, the thermoelectric efficiency of a thermoelectric material can be evaluated by the thermoelectric figure of merit ZT by using the following equation:

ZT=S²Tσ/κ

wherein S is the thermoelectric power or Seebeck coefficient, T is the temperature, σ is the electrical conductivity, and κ is the thermal conductivity.

Generally, the thermoelectric figure of merit ZT can be increased by increasing the electrical conductivity of the material, which is generally achieved by doping of a small amount of carriers. However, such a processing causes a reduction in Seebeck coefficient. Namely, mutual restraint exists between the electrical conductivity and Seebeck coefficient. Thus, using such conductive polymer materials as thermoelectric elements requires massive doping experiments to find the best ratio of the two parameters.

In view of the above technical problems that cannot be effectively solved and overcome, the present invention provides an element using a material capable of carrying out photovoltaics and cooperating with transport doping for selective conduction of positive/negative charge carrier, both of which, when mixed in any non-conductive or conductive polymer, can form a semiconductor material with the properties of semiconductor materials of P-type, N-type or both; namely, an element that can generate a potential difference when subject to light or a temperature difference or generate light or a temperature difference when an applied potential difference is applied.

### BRIEF SUMMARY OF THE INVENTION

The technical problem is solved by the present invention which uses an organic material to form a thermoelectric element.

A thermoelectric element according to the present invention includes a first subelement and a second subelement. The first subelement includes three main ingredients: a charge generation material made of organic or organic metal pigment or dye, an organic hole transport material, and a binder. A second subelement is superimposed on the first subelement and includes three main ingredients: a charge generation material made of organic or organic metal pigment or dye, an organic electron transport material, and a binder.

Each of the three main ingredients of the first subelement and the three main ingredients of the second subelement is capable of uniformly dispersed or dissolved in at least one solvent.

The organic hole transport material can include: (1) at least one nitrogen atom, such as hydrozone, triphenylamine, and phenylenediamine; and (2) at least one non benzene ring upper double bond, such as stilbene and butadiene. The above compounds can be used independently or combined with each other.

The organic electron transport material can include: (1) a carbonyl compound, such as diphenylquinone and phenanthrenequinone; (2) a sulfonyl compound; and (3) a heterocyclic compound, such as pyrazolidine thiophene. The above compounds can be used independently or combined with each other.

The charge generation material made of organic or organic metal pigment or dye can include phthalocyanine, metal-free phthalocyanine, azo, such as bisazo and triazo, squarylium, azulium, perylene, and naphthalocyanine, and wherein the above pigments or dyes can be used independently or combined with each other.

The binder can include: (1) thermoplastic resins, such as a styrene polymer, a butadiene styrene copolymer, a acrylonitrile styrene copolymer, a styrene maleic acid copolymer, an acrylic copolymer, a styrene acrylic copolymer, polyethylene, ethylene vinyl acetate copolymer, chlorinated polyethylene, polyvinyl chloride, polypropylene, a vinylchloride vinylacetate copolymer, polyester, an alkyd resin, a ketone, polyamide, polyurethane, polycarbonate, polyarylate, polysulphone, a diallyl phthalate resin, a polyvinyl butyral resin, and a polyether resin; (2) a cross-linked thermoset resin, such as a silicone resin, an epoxy resin, a phenolic resin, a urea resin, a melamine resin, and other cross-linked thermoset resins; and (3) a photo-curing resin, such as epoxy acrylate and a polyurethane acrylic resin. The above resins can be used independently or combined with each other.

The solvent can include: (1) an alcohol, such as methanol or ethanol; (2) a hydrocarbon solvent containing at least four carbon atoms, such as n-hexane or cyclohexane; (3) an aromatic solvent, such as toluene or dimethylbenzene; (4) halo cantaining solvent, such as dichloromethane, dichloroethane, or chlorobenzene; (5) an ether, such as tetrahydrofuran or ethylene glycol dimethyl ether; (6) a ketone, such as acetone or butanone; (7) an ester, such as ethyl acetate or butyl acetate; (8) a solvent containing at least one nitrogen atom, such as dimethyl formamide; (9) a solvent containing at least one sulfur atom, such as dimethyl sulfoxide; and (10) water. The above solvents can be used independently or combined with each other.

Each of the first subelement and the second subelement can include a charge transport layer having a thickness of 0.01-3000 μm, preferably 20-100 μm.

The present invention will become clearer in light of the following detailed description of illustrative embodiments of this invention described in connection with the drawings.

### DESCRIPTION OF THE DRAWINGS

FIG. 1 is a diagrammatic view of a thermoelectric element according to the present invention.

FIG. 2 is an exploded, perspective view of the thermoelectric element according to the present invention.

FIG. 3 is a diagram illustrating experimental data of the thermoelectric element according to the present invention.

### DETAILED DESCRIPTION OF THE INVENTION

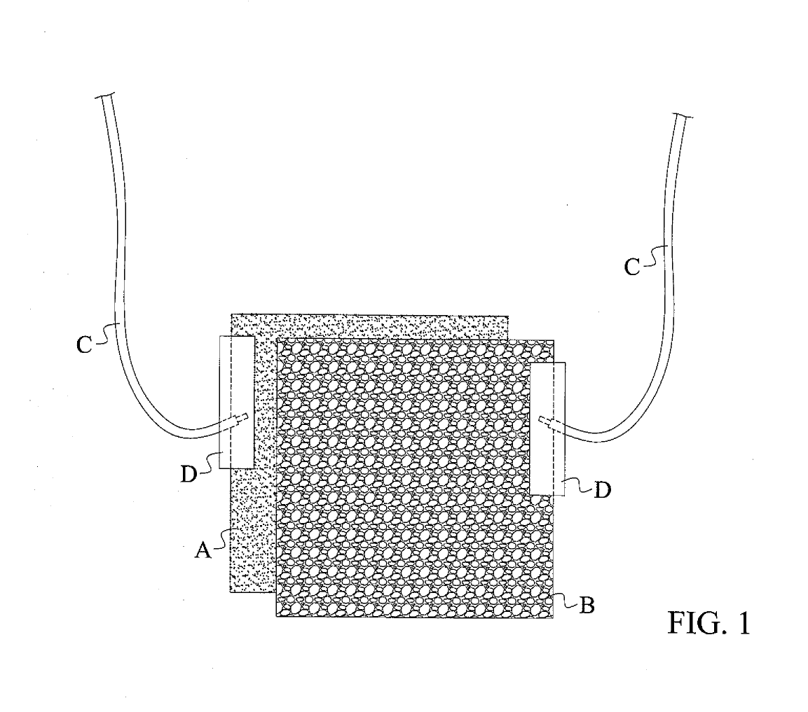

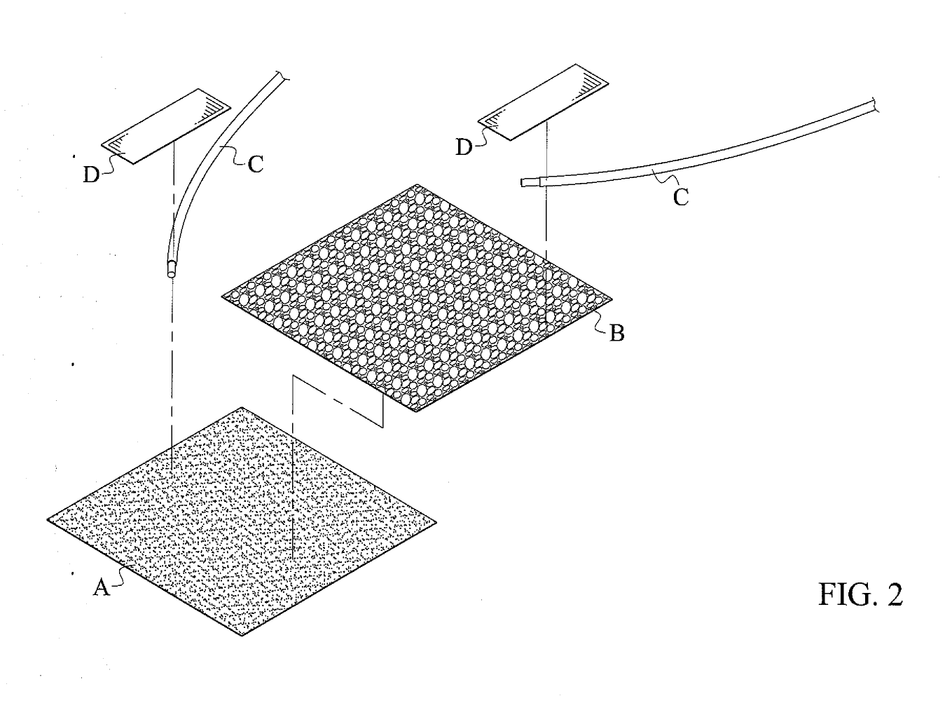

FIGS. 1 and 2 are a diagrammatic view and an exploded, perspective view of a thermoelectric element according to the present invention, respectively. The thermoelectric element according to the present invention includes a first subelement A and a second subelement B. The first subelement A and the second subelement B are superimposed each other.

The first subelement A includes three main ingredients: a charge generation material (CGM) made of organic or organic metal pigment or dye, an organic hole transport material (HTM), and a binder.

The second subelement B includes three main ingredients: a charge generation material (CGM) made of organic or organic metal pigment or dye, an organic electron transport material (ETM), and a binder.

Each main ingredient of the first subelement A and the second subelement B can be uniformly dispersed or dissolved in an organic solvent or water.

The organic hole transport material (HTM) can be any one of the following compounds or a combination thereof, including: (1) at least one nitrogen atom, such as hydrozone, triphenylamine, and phenylenediamine; and (2) at least one non benzene ring upper double bond, such as stilbene and butadiene. The above compounds can be used independently or combined with each other.

The organic electron transport material (ETM) can be any one of the following compounds or a combination thereof, including: (1) a carbonyl compound, such as diphenylquinone and phenanthrenequinone; (2) a sulfonyl compound; and (3) a heterocyclic compound, such as pyrazolidine thiophene. The above compounds can be used independently or combined with each other.

The charge generation material (CGM) made of organic or organic metal pigment or dye includes phthalocyanine, metal-free phthalocyanine, azo, such as bisazo, triazo, squarylium, azulium, perylene, and naphthalocyanine. The above pigments or dyes can be used independently or combined with each other.

The binder can be any one of the following compounds or a combination thereof, including: (1) thermoplastic resins, such as a styrene polymer, a butadiene styrene copolymer, a acrylonitrile styrene copolymer, a styrene maleic acid copolymer, an acrylic copolymer, a styrene acrylic copolymer, polyethylene, ethylene vinyl acetate copolymer, chlorinated polyethylene, polyvinyl chloride, polypropylene, a vinylchloride vinylacetate copolymer, polyester, an alkyd resin, a ketone, polyamide, polyurethane, polycarbonate, polyarylate, polysulphone, a diallyl phthalate resin, a polyvinyl butyral resin, and a polyether resin; (2) a cross-linked thermoset resin, such as a silicone resin, an epoxy resin, a phenolic resin, a urea resin, a melamine resin, and other cross-linked thermoset resins; and (3) a photo-curing resin, such as epoxy acrylate and a polyurethane acrylic resin. The above resins can be used independently or combined with each other.

Examples of the solvent include: (1) an alcohol, such as methanol or ethanol; (2) a hydrocarbon solvent containing at least four carbon atoms, such as n-hexane or cyclohexane; (3) an aromatic solvent, such as toluene or dimethylbenzene; (4) halo cantaining solvent, such as dichloromethane, dichloroethane, or chlorobenzene; (5) an ether, such as tetrahydrofuran or ethylene glycol dimethyl ether; (6) a ketone, such as acetone or butanone; (7) an ester, such as ethyl acetate or butyl acetate; (8) a solvent containing at least one nitrogen atom, such as dimethyl formamide; (9) a solvent containing at least one sulfur atom, such as dimethyl sulfoxide; and (10) water. The above solvents can be used independently or combined with each other.

Each main ingredient of the first and second subelements A and B can be dissolved or dispersed by using a solvent. The ratio of the weight of the charge generation material (CGM) of organic or organic metal pigment or dye to the weight of the organic hole transport material (HTM) is in a range between 1:99 and 99:1, preferably between 60:40 and 40:60. The ratio of the weight of the charge generation material (CGM) of organic or organic metal pigment or dye to the weight of the organic electron transport material (ETM) is in a range between 1:99 and 99:1, preferably between 60:40 and 40:60. The ratio of the weight of the binder to the sum of the weight of the charge generation material (CGM) of organic or organic metal pigment or dye and the weight of the organic hole transport material (HTM) is in a range between 1:99 and 99:1, preferably between 60:40 and 40:60.

Each of the first subelement A and the second subelement B includes a charge transport layer having a thickness of 0.01-3000 μm, preferably 1-500 μm, and most preferably 20-100 μm.

A method for producing the thermoelectric element according to the present invention includes the following steps:

Preparation: Firstly, two liquid paints (a P-type hole transport type semiconductor paint and an N-type electron transport type semiconductor paint) are prepared. Each liquid paint includes at least three main ingredients and at least one polymer material. The polymer material can be dissolved or dispersed in at least one solvent or water. At least one of the two paints includes at least a conductive simple material or a conductive compound. The two paints can be converted from the liquid state into the solid state by natural drying, dry heating, photo-curing, or adding a curing agent. Furthermore, two metal wires C are prepared and serves as a channel for outward transmission of the voltage and the current of the thermoelectric element.

Application: Dip a brush in the P-type hole transport type semiconductor paint and slowly apply the P-type hole transport type semiconductor paint on a sheet of polyethylene (PE). Each of a length and a width of the sheet of PE is about 3 cm. Then, the N-type electron transport type semiconductor paint is applied on another sheet of PE. The procedure is the same as the previous one. The area of application is substantially the same as that of the P-type hole transport type semiconductor paint.

Drying: The sheet of PE applied with the P-type hole transport type semiconductor paint is placed into an oven and is baked at a temperature of 50-120□ until the sheet of PE is completely dried, and a first subelement A is obtained after natural cooling. Then, the sheet of PE applied with the N-type hole transport type semiconductor paint is placed into an oven and is baked at a temperature of 50-120° C. until the sheet of PE is completely dried, and a second subelement B is obtained after natural cooling.

Superimposition: The second subelement B is superimposed on the first element A. However, an area of a width of about 5 mm at a side of the first subelement A is not covered.

Fixing metal wires C: The two metal wires C are respectively fixed to two opposite ends respectively of the first and second subelements A and B by two heat resistant adhesive tapes D. Then, a conductive paint (a liquid) is applied to provide connection between the two metal wires C and the first and second subelements A and B.

Redrying: The first and second subelements A and B connected to the two metal wires C are placed into an oven and are baked at a temperature of 50-120° C. until the conductive paint is completely dried. A thermoelectric element is obtained after natural drying.

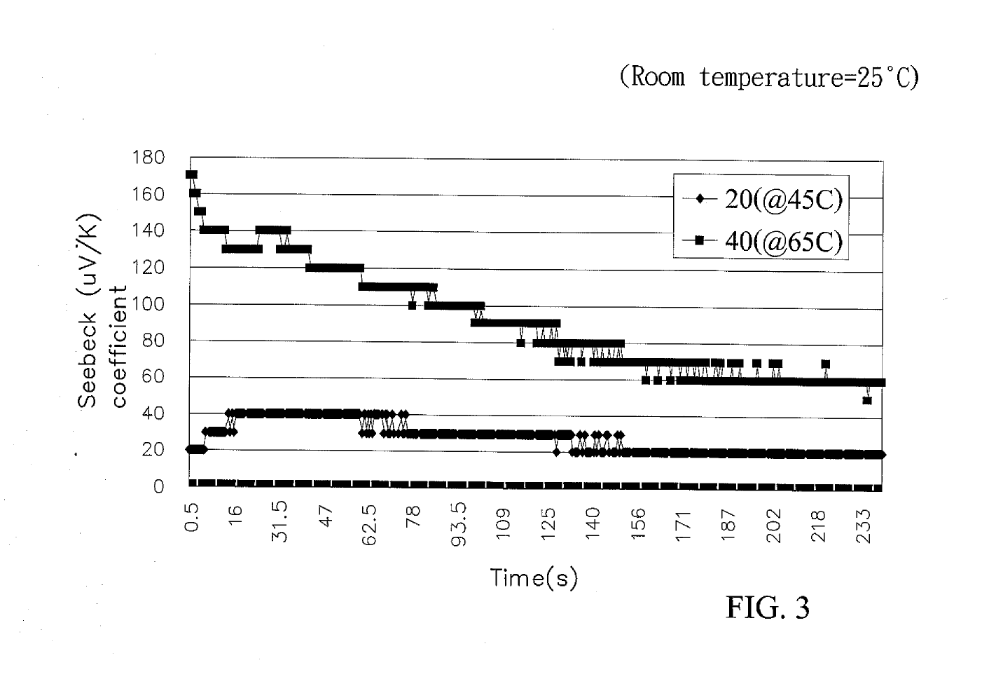

With reference to FIG. 3, the thermoelectric element includes a P-type organic material and an N-type organic material (namely, the first subelement A and the second subelement B) which are superimposed on each other. One of the two metal wires C is connected to a side of the first subelement A, and the other metal wire C is connected to a side of the second subelement B. During experiments, the thermoelectric element was clamped in a device having a temperature difference design, temperature differences of 20° C. and 40° C. were applied, and an automatic voltage pick-up device was used to continuously read the voltage change. As shown in FIG. 3, an obvious generation of voltage can be obtained by applying a temperature difference on the thermoelectric element.

Although specific embodiments have been illustrated and described, numerous modifications and variations are still possible without departing from the scope of the invention. The scope of the invention is limited by the accompanying claims.

1. A thermoelectric element comprising:
a first subelement including three main ingredients, wherein the three main ingredients of the first subelement includes a charge generation material made of organic or organic metal pigment or dye, an organic hole transport material, and a binder; and
a second subelement superimposed on the first subelement and including three main ingredients, wherein the three main ingredients of the second subelement includes a charge generation material made of organic or organic metal pigment or dye, an organic electron transport material, and a binder.

2. The thermoelectric element as claimed in claim 1, wherein each of the three main ingredients of the first subelement and the three main ingredients of the second subelement is capable of uniformly dispersed or dissolved in at least one solvent.

3. The thermoelectric element as claimed in claim 1, wherein the organic hole transport material includes:
(1) at least one nitrogen atom, such as hydrozone, triphenylamine, and phenylenediamine; and
(2) at least one non benzene ring upper double bond, such as stilbene and butadiene,
wherein the above compounds are used independently or combined with each other.

4. The thermoelectric element as claimed in claim 1, wherein the organic electron transport material includes:
(1) a carbonyl compound, such as diphenylquinone and phenanthrenequinone;
(2) a sulfonyl compound; and
(3) a heterocyclic compound, such as pyrazolidine thiophene, wherein the above compounds are used independently or combined with each other.

5. The thermoelectric element as claimed in claim 1, wherein the charge generation material made of organic or organic metal pigment or dye includes phthalocyanine, metal-free phthalocyanine, azo, such as bisazo and triazo, squarylium, azulium, perylene, and naphthalocyanine, and wherein the above pigments or dyes are used independently or combined with each other.

6. The thermoelectric element as claimed in claim 1, wherein the binder includes:
(1) thermoplastic resins, such as a styrene polymer, a butadiene styrene copolymer, a acrylonitrile styrene copolymer, a styrene maleic acid copolymer, an acrylic copolymer, a styrene acrylic copolymer, polyethylene, ethylene vinyl acetate copolymer, chlorinated polyethylene, polyvinyl chloride, polypropylene, a vinylchloride vinylacetate copolymer, polyester, an alkyd resin, a ketone, polyamide, polyurethane, polycarbonate, polyarylate, polysulphone, a diallyl phthalate resin, a polyvinyl butyral resin, and a polyether resin;
(2) a cross-linked thermoset resin, such as a silicone resin, an epoxy resin, a phenolic resin, a urea resin, a melamine resin, and other cross-linked thermoset resins; and
(3) a photo-curing resin, such as epoxy acrylate and a polyurethane acrylic resin,
wherein the above resins are used independently or combined with each other.

7. The thermoelectric element as claimed in claim 3, wherein the solvent includes:
(1) an alcohol, such as methanol or ethanol;
(2) a hydrocarbon solvent containing at least four carbon atoms, such as n-hexane or cyclohexane;
(3) an aromatic solvent, such as toluene or dimethylbenzene;
(4) halo cantaining solvent, such as dichloromethane, dichloroethane, or chlorobenzene;
(5) an ether, such as tetrahydrofuran or ethylene glycol dimethyl ether;
(6) a ketone, such as acetone or butanone;
(7) an ester, such as ethyl acetate or butyl acetate;
(8) a solvent containing at least one nitrogen atom, such as dimethyl formamide;
(9) a solvent containing at least one sulfur atom, such as dimethyl sulfoxide; and
(10) water,
wherein the above solvents are used independently or combined with each other.

8. The thermoelectric element as claimed in claim 1, wherein each of the first subelement and the second subelement includes a charge transport layer having a thickness of 0.01-3000 μm.

9. The thermoelectric element as claimed in claim 8, wherein the thickness of the charge transport layer is 20-100 μm.
